(19) United States
(12) Patent Application Publication
(10) Pub. No.: US 2018/0301487 A1
(43) Pub. Date: Oct. 18, 2018

(54) IMAGE SENSOR

(71) Applicant: SAMSUNG ELECTRONICS CO., LTD., Suwon-si (KR)

(72) Inventors: Gwi-Deok Ryan LEE, Suwon-si (KR); Tae Yon LEE, Seoul (KR); Kwang Min LEE, Seoul (KR); Masaru ISHII, Hwaseong-si (KR)

(21) Appl. No.: 15/804,183

(22) Filed: Nov. 6, 2017

(30) Foreign Application Priority Data
Apr. 12, 2017 (KR) 10-2017-0047514

(51) Int. Cl. H01L 27/146; H04N 5/378; H04N 5/3745

(52) U.S. Cl. CPC H01L 27/14614; H04N 5/378; H01L 27/14636; H01L 27/1463; H04N 5/3745

(57) ABSTRACT

An image sensor includes first photoelectric elements, second photoelectric elements under the first photoelectric elements, and a pixel circuit including first semiconductor devices and second semiconductor devices under second photoelectric elements. The first semiconductor devices are connected to at least one of the first photoelectric elements. The second semiconductor devices are connected to at least one of the second photoelectric elements. The first semiconductor devices are connected to different first photoelectric elements and are in one of a plurality of pixel regions.

### CROSS-REFERENCE TO RELATED APPLICATION(S)

Korean Patent Application No. 10-2017-0047514, filed on Apr. 12, 2017, and entitled, “Image Sensor,” is incorporated by reference herein in its entirety.

### BACKGROUND

### 1. Field

One or more embodiments described herein relate to an image sensor.

### 2. Description of the Related Art

Semiconductor-based image sensors detect light and generate corresponding electrical signals. One type of image sensor includes pixel arrays having a plurality of pixels, circuits driving pixel arrays, and the like. Image sensors may be used in smartphones, tablet PCs, laptop computers, television sets, and camera modules for capturing images or moving pictures.

### SUMMARY

In accordance with one or more embodiments, an image sensor includes a plurality of pixel regions, a plurality of first photoelectric elements; a plurality of second photoelectric elements beneath the plurality of first photoelectric elements; and a pixel circuit including first semiconductor devices and second semiconductor devices beneath the plurality of second photoelectric elements, the first semiconductor devices connected to at least one of the plurality of first photoelectric elements and the second semiconductor devices connected to at least one of the plurality of second photoelectric elements, wherein the first semiconductor devices are connected to different first photoelectric elements among the plurality of first photoelectric elements and are in one of the plurality of pixel regions.

In accordance with one or more other embodiments, an image sensor includes a semiconductor substrate including a plurality of pixel regions; a plurality of first photoelectric elements on a semiconductor substrate; a plurality of second photoelectric elements in the semiconductor substrate; a pixel circuit beneath the plurality of second photoelectric elements and including first semiconductor devices electrically connected to at least one of the plurality of first photoelectric elements and second semiconductor devices electrically connected to at least one of the plurality of second photoelectric elements; and via electrodes penetrating through the semiconductor substrate and connecting the first semiconductor devices to at least one of the plurality of first photoelectric elements, wherein portions of the first semiconductor devices connected to one of the via electrodes are in different pixel regions among the plurality of pixel regions.

In accordance with one or more other embodiments, an image sensor which includes first to third pixel groups adjacent to each other, wherein each of the first to third pixel groups includes a plurality of first photoelectric elements, a plurality of second photoelectric elements beneath the plurality of first photoelectric elements, and a pixel circuit including first semiconductor devices and second semiconductor devices beneath the plurality of second photoelectric elements, and wherein at least one of the first semiconductor devices in the first pixel group is connected to at least one of the plurality of first photoelectric elements in the second pixel group, and at least one of the second semiconductor devices in the first pixel group is connected to at least one of the plurality of second photoelectric elements in the third pixel group.

### BRIEF DESCRIPTION OF DRAWINGS

Features will become apparent to those of skill in the art by describing in detail exemplary embodiments with reference to the attached drawings in which:

FIG. 1 illustrates an embodiment of an image processing apparatus;

FIGS. 2A and 2B illustrate embodiments of pixel circuits;

FIGS. 3A to 3C illustrate other embodiments of pixel circuits;

FIG. 4 illustrates an embodiment of a connection structure in an image sensor;

FIG. 5 illustrates a layout embodiment of a semiconductor device;

FIG. 6 illustrates another layout embodiment of a semiconductor device;

FIG. 7 illustrates a cross-sectional embodiment of an image sensor;

FIG. 8 illustrates another cross-sectional embodiment of an image sensor; and

FIG. 9 illustrates an embodiment of an electronic device.

### DETAILED DESCRIPTION

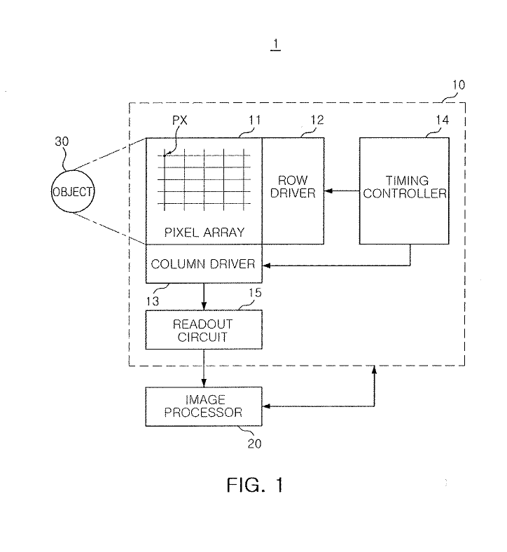

FIG. 1 illustrates an embodiment of an image processing apparatus 1 which may include an image sensor 10 and an image processor 20. The image sensor 10 may include a pixel array 11, a row driver 12, a column driver 13, a timing controller 14, and a readout circuit 15.

The image sensor 10 may operate according to a control command from the image processor 20, may convert light transmitted from an object 30 to an electrical signal, and may output the electrical signal to the image processor 20. The pixel array 11 in the image sensor 10 may include a plurality of pixels PX. The plurality of pixels PX may include a photoelectric element that receives light and generates a corresponding electric charge. The photoelectric element may be, for example, a photodiode (PD). In an example embodiment, each of the plurality of pixels PX may include two or more photoelectric elements, and two or more photoelectric elements in one pixel PX may receive light of different colors and generate corresponding electric charges.

Each of the plurality of pixels PX may include a pixel circuit generating an electrical signal from the electrical charge generated by the photoelectric element. In an example embodiment, the pixel circuit may include a transfer transistor, a drive transistor, a select transistor, and a reset transistor. For example, when one pixel PX includes two or more photoelectric elements, each pixel PX may include a pixel circuit to process charges generated by the two or more photoelectric elements, respectively. For example, when one pixel PX has two or more photoelectric elements, the pixel circuit may include at least two or more portions, for example, of the transfer transistor, the drive transistor, the select transistor, and the reset transistor.

In an example embodiment, one pixel PX may include a first photoelectric element and a second photoelectric element. The first photoelectric element and the second photoelectric element may receive light in different wavelength bands to generate corresponding charges, respectively. In an example embodiment, the first photoelectric element may be an organic photodiode and may generate a charge from light in a wavelength band corresponding to green light. The second photoelectric element may be a semiconductor photodiode and may generate a charge from light in a wavelength band corresponding to blue or red light. In an example embodiment, the first photoelectric element may receive light before the second photoelectric element receives the light based on, for example, a traveling direction of light.

In an example embodiment, one pixel PX may include a first circuit processing a charge generated in the first photoelectric element and a second circuit processing a charge generated in the second photoelectric element. The first circuit may include a plurality of first semiconductor devices. The second circuit may include a plurality of second semiconductor devices. The first circuit may generate a first electrical signal from the charge generated in the first photoelectric element and may output the first electrical signal to a first column line. The second circuit may generate a second electrical signal from the charge generated in the second photoelectric element and may output the second electrical signal to a second column line.

In an example embodiment, two or more first circuits adjacent to each other may share one first column line. In a similar manner, two or more second circuits adjacent to each other may share one second column line. The second circuits adjacent to each other may also share a portion of the second semiconductor devices.

The row driver 12 may drive the pixel array 11 on a row basis. For example, the row driver 12 may generate a transfer control signal for controlling the transfer transistor of a respective pixel PX, a reset control signal for controlling the reset transistor, and a select control signal for controlling the select transistor.

The column driver 13 may include a correlated double sampler (CDS) and an analog-to-digital converter (ADC). The correlated double sampler may perform correlated double sampling, by receiving an electrical signal through column lines connected to pixels PX in a row selected by a row select signal supplied by the row driver 12. The analog-to-digital converter may convert an output from the correlated double sampler to a digital signal and transmit the digital signal to the readout circuit 15.

The readout circuit 15 may include, for example, a latch or buffer circuit and an amplification circuit. The latch or buffer circuit may temporarily store a digital signal. For example, the readout circuit 15 may temporarily store or amplify the digital signal from the column driver 13 and generate image data. Operation timings of the row driver 12, the column driver 13, and the readout circuit 15 may be determined by the timing controller 14. The timing controller 14 may operate based on a control command transmitted by the image processor 20. The image processor 20 may perform signal processing on image data transmitted by the readout circuit 15 and output the signal-processed image data to a display device or the like, or store the signal-processed image data in a storage device such as a memory or the like.

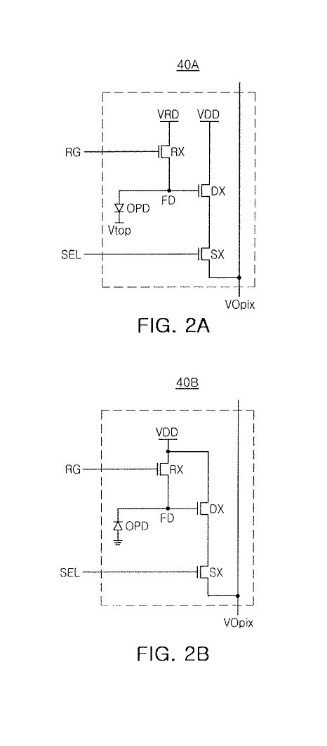

FIGS. 2A and 2B illustrate circuit embodiments of pixel circuits 40A and 40B in an image sensor. The pixel circuits illustrated in FIGS. 2A and 2B may generate electrical signals using charges generated in an organic photodiode OPD in each pixel.

Referring to FIG. 2A, the pixel circuit 40A may include a plurality of transistors in a 3T circuit structure. In an example embodiment, the pixel circuit 40A may include a reset transistor RX, a drive transistor DX, and a select transistor SX. A gate terminal of the drive transistor DX may be connected to a floating diffusion FD. Charges generated in the organic photodiode OPD may be accumulated in the floating diffusion FD. In an example embodiment, the organic photodiode OPD may include first and second electrodes parallel with each other, with an organic photoconversion layer therebetween. The organic photoconversion layer may receive light of a predetermined wavelength band to generate electrical charges.

The drive transistor DX may operate as a source follower buffer amplifier by electrical charges accumulated in the floating diffusion FD. The drive transistor DX may amplify the electrical charges accumulated in the floating diffusion FD and transfer the amplified electrical charges to the select transistor SX.

The select transistor SX may be operated based on a select control signal SEL input by a row driver, and may perform switching and addressing operations. For example, when the select control signal SEL is applied from the row driver, a first pixel signal VOpix may be output to a first column line connected to the select transistor SX. The first pixel signal VOpix may be detected by a column driver and a readout circuit.

The reset transistor RX may be operated based on a reset control signal RG input by the row driver. The reset transistor RX may reset a voltage of the floating diffusion FD to a readout voltage VRD in response to the reset control signal RG.

In the example embodiment of FIG. 2A, the organic photodiode OPD may use holes as main charge carriers. For example, when holes are used as the main charge carriers, a cathode of the organic photodiode OPD may be connected to the floating diffusion FD and an anode of the organic photodiode OPD may be connected to an upper electrode voltage Vtop. In an example embodiment, the upper electrode voltage Vtop may have voltage of a few volts, for example, about 3.0 V. Since holes are generated as main charge carriers in the organic photodiode OPD, a drain terminal of the reset transistor RX may be connected to a readout voltage VRD, which has a voltage level different from a power supply voltage VDD. Dark current characteristics may be improved by implementing pixel circuit 40A using holes as the main charge carriers.

Referring to FIG. 2B, a pixel circuit 40B may be a 3T circuit including a reset transistor RX, a drive transistor DX, and a select transistor SX. Compared with the example embodiment of FIG. 2A, in an example embodiment illustrated in FIG. 2B, an organic photodiode OPD may use electrons as the main charge carriers. Since electrons are generated as the main charge carriers, an anode of the organic photodiode OPD may be connected to a floating diffusion FD, and a cathode of the organic photodiode OPD may be connected to a ground voltage. A drain terminal of the reset transistor RX and a drain terminal of the drive transistor DX may be connected to a power supply voltage VDD.

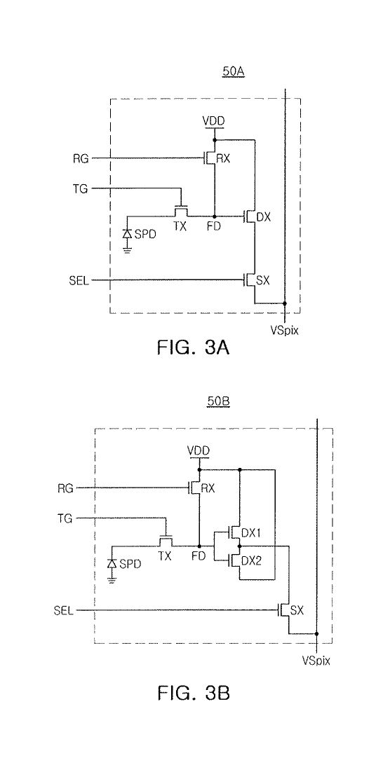

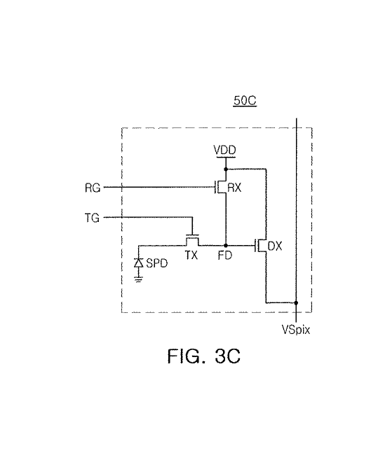

FIGS. 3A to 3C illustrate additional circuit embodiments of pixel circuits 50A, 50B, and 50C in an image sensor. In an example embodiment, the pixel circuits illustrated in FIGS. 3A to 3C may generate electrical signals using charges generated in a semiconductor photodiode in each pixel.

Referring to FIG. 3A, the pixel circuit 50A may be a 4T circuit including four transistors. The pixel circuit 50A may further include a transfer transistor TX, in addition to the reset transistor RX, the drive transistor DX, and the select transistor SX. A photoelectric element SPD connected to the pixel circuit 50A may be a semiconductor photodiode on a semiconductor substrate including silicon or the like, and may be connected to a floating diffusion FD through the transfer transistor TX. For example, different from the example embodiment illustrated in FIGS. 2A and 2B, a cathode or an anode of the photoelectric element SPD may not be directly connected to the floating diffusion FD.

The transfer transistor TX may transfer charges, accumulated in the photoelectric element SPD to the floating diffusion FD, based on a transfer control signal TG transmitted by a row driver. The photoelectric element SPD may generate electrons as main charge carriers. Operations of the reset transistor RX, the drive transistor DX, and the select transistor SX may be similar to those described above with reference to FIGS. 2A and 2B. A second pixel signal VSpix may be output through a second column line connected to the select transistor SX. The second pixel signal VSpix may be detected by a column driver and a readout circuit.

Referring to FIG. 3B. the pixel circuit 50B may include a select transistor SX, a reset transistor RX, a transfer transistor TX, a first drive transistor DX1, and a second drive transistor DX2. The pixel circuit 50B may include a plurality of drive transistors DX1 and DX2 connected in parallel with each other. By connecting the plurality of drive transistors DX1 and DX2 in parallel, deterioration of random telegraph signal (RTS) noise characteristics may be reduced or eliminated.

Referring to FIG. 3C, a pixel circuit 50C may include a drive transistor DX, a reset transistor RX, and a transfer transistor TX. For example, when the transfer transistor TX is turned on based on a transfer control signal TG, an electrical charge generated in the photoelectric element SPD may be transferred to a floating diffusion FD, and the drive transistor DX may amplify the electrical charge to output a second pixel signal VSpix. In the example embodiment of FIG. 3C, the pixel circuit 50C may not include a select transistor.

Each of the pixel circuits 50A, 50B, and 50C of the embodiments illustrated in FIGS. 3A to 3C may include the transfer transistor TX. The transfer transistor TX may be controlled by the transfer control signal TG. Whether a charge generated in the photoelectric element SPD is transmitted to the floating diffusion FD may be determined by the transfer control signal TG. Thus, the drive transistor DX, the reset transistor RX, the select transistor SX, and the like, except for the transfer transistor TX, may be shared by adjacent pixels.

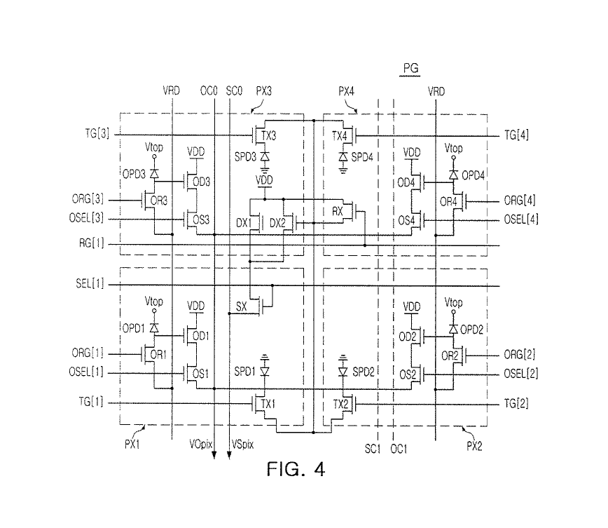

FIG. 4 illustrates an embodiment of a connection structure of column lines and pixel circuits, which, for example, may be in one or more of the image sensor embodiments described herein.

Referring to FIG. 4, adjacent pixels may form one pixel group PG which may include four pixels PX1 to PX4 arranged in a 2×2 matrix. Each of the four pixels PX1 to PX4 in the pixel group PG may include a first circuit and a second circuit. The first circuits in the pixel group PG may be connected to first photodiodes OPD1 to OPD4 (e.g., organic photodiodes), respectively, to generate a first pixel signal VOpix. The second circuits in the pixel group PG may be connected to the second photoelectric elements SPD1 to SPD4 (e.g., semiconductor photodiodes), respectively, to generate a second pixel signal VSpix. The first pixel signal VOpix and the second pixel signal VSpix may be output through a first column line OC0 and a second column line SC0, respectively.

The first circuit in each of the pixels PX1 to PX4 may be implemented as a 3T circuit including three transistors. In an example embodiment, the first circuit in the first pixel PX1 may include a reset transistor OR1, a drive transistor OD1, and a select transistor OS1. The reset transistor OR1 and the select transistor OS1 may be controlled by a reset signal ORG[1] and a select signal OSEL[1] input by a row driver, respectively. In each scanning period, the row driver may turn on only one of four select transistors OS1 to OS4 in the first circuits of one pixel group PG. Thus, a plurality of first circuits in the pixel group PG may share one first column line OC0.

Each of the second circuits may be implemented as a 4T circuit that includes four transistors. In an example embodiment, a second circuit of the first pixel PX1 may include a transfer transistor TX1, a reset transistor RX, a select transistor SX, a first drive transistor DX1, and a second drive transistor DX2. The reset transistor RX, the select transistor SX, the first drive transistor DX1, and the second drive transistor DX2 may also be connected to transfer transistors TX2 to TX4, which are included in other pixels. For example, the second circuits in one pixel group PG may share the reset transistor RX, the select transistor SX, the first drive transistor DX1, and the second drive transistor DX2.

The transfer transistors TX1 to TX4 in one pixel group PG may be controlled by different transfer signals TG[1] to TG[4], respectively. In each scanning period, the row driver may only turn on one of the transfer transistors TX1 to TX4 using the input transfer signals TG[1] to TG[4]. Thus, a plurality of second circuits in the pixel group PG may share the reset transistor RX, the select transistor SX, the first drive transistor DX1, the second drive transistor DX2, and the second column line SC0.

In an example embodiment, the output order of the first pixel signal VOpix and the second pixel signal VSpix through the first column line OC0 and the second column line SC0 may be the same. For example, the select transistor OS1 of the first pixel PX1 may be turned on in a first scanning period. The select transistors OS2 to OS4 in other pixels PX2 to PX4 may all be turned off. Thus, the first pixel signal VOpix, generated by the first circuit of the first pixel PX1 using a charge of the first photoelectric element, may be output through the first column line OC0 during a first scanning period.

Simultaneously, in the first scanning period, the transfer transistor TX1 of the first pixel PX1 may be turned on. All the transfer transistors TX2 to TX4 in other pixels may be turned off Thus, the second pixel signal VSpix, generated by the second circuit of the first pixel PX1, may be output through the second column line SC0 during the first scanning period. By turning on only one of the select transistors OS1 to OS4 and turning on only one of the transfer transistors TX1 to TX4 in respective scanning periods in the same manner as described above, each of the first and second circuits in one pixel group PG may share the first column line OC0 and the second column line SC0.

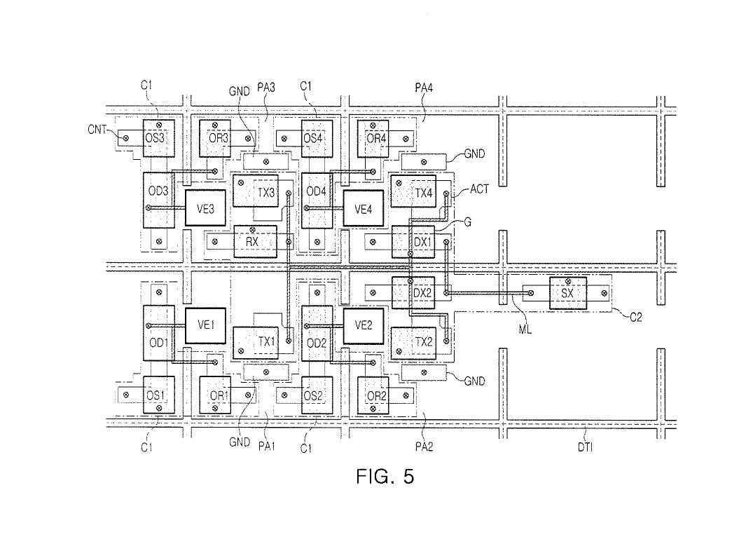

FIG. 5 illustrates a layout embodiment of semiconductor devices in a pixel circuit of an image sensor, which, for example, may correspond to one or more of the image sensor embodiments described herein. By forming the semiconductor devices in the manner as in an example embodiment illustrated in FIG. 5, the pixel circuit may be provided according to the example embodiment illustrated in FIG. 4. As an example embodiment, FIG. 5 may only illustrate semiconductor devices providing a pixel circuit according to the example embodiment of FIG. 4.

Referring to FIG. 5, an image sensor according to an example embodiment may include a pixel separation region DTI and a plurality of pixel regions PA1 to PA8 defined by the pixel separation region DTI. The pixel separation region DTI may be a deep trench isolation region and may significantly reduce electrical and optical crosstalk between photoelectric elements in each of the pixel regions PA1 to PA8. The pixel separation region DTI may include oxide or the like. A sidewall of the pixel separation region DTI may be formed of a material having a predetermined, relatively high reflectivity, e.g., polysilicon containing boron.

Each of the pixel regions PA1 to PA8 may include a plurality of semiconductor devices, with photoelectric elements under the semiconductor devices. The photoelectric elements may be beneath the semiconductor devices in one direction (e.g., a z-axis direction) and may include a first photoelectric element and a second photoelectric element. In an example embodiment, the first photoelectric element may be an organic photodiode and the second photoelectric element may be a semiconductor photodiode. The second photoelectric element may be between the semiconductor devices and the first photoelectric element in one direction, for example, the z-axis direction.

The photoelectric elements OPD1 to OPD4 and SPD1 to SPD4, in each of the first to fourth pixels PX1 to PX4 and illustrated in the pixel circuit of FIG. 4, may be in each of the first to fourth pixel regions PA1 to PA8. For example, in the first pixel region PA1, the first photoelectric element OPD1 and the second photoelectric element SPD1 in the first pixel PX1 may be stacked on each other. Similarly, in the second pixel region PA2, the first photoelectric element OPD2 and the second photoelectric element SPD2 in the second pixel PX2 may be stacked on each other.

A layout embodiment of semiconductor devices implementing the pixel group PG according to the example embodiment of FIG. 4 will be described with reference to FIG. 5. In an example embodiment of FIG. 5, each of the semiconductor devices may include an active region ACT providing a source/drain region and a gate electrode G intersecting the active region ACT.

Referring to FIG. 5, in first to fourth pixel regions PA1 to PA4, reset transistors OR1 to OR4 may be connected to first photoelectric elements OPD1 to OPD4 of first to fourth pixels PX1 to PX4. In an example embodiment, the reset transistors OR1 to OR4 in the first to fourth pixel regions PA1 to PA4 may be arranged, respectively, adjacent to the pixel separation region DTI.

According to an example embodiment, drive transistors OD1 to OD4 and select transistors OS1 to OS4 connected to the first photoelectric elements OPD1 to OPD4, respectively, may be in pixel regions PA1 to PA8, different from pixel regions of the first photoelectric elements OPD1 to OPD4. With reference to FIG. 5, the drive transistor OD1 and the select transistor OS1, connected to the first photoelectric element OPD1 of the first pixel PX1, may be in a fifth pixel region PAS other than the first pixel region PAL Similarly, the drive transistor OD4 and the select transistor OS4, connected to the first photoelectric element OPD4 of a fourth pixel region PA4, may be in a third pixel region PA3, other than the fourth pixel region PA4.

In an example embodiment, the drive transistors OD1 to OD4 and the select transistors OS1 to OS4 may be adjacent to the pixel separation region DTI and may have active regions ACT connected to each other. Referring to FIG. 5, active regions ACT of the drive transistors OD1 to OD4 may be connected to active regions ACT of the select transistors OS1 to OS4, respectively. The active regions ACT of the select transistors OS1 to OS4 may extend in a first direction (e.g., x-axis direction). The active regions ACT of the drive transistors OD1 to OD4 may extend in a second direction intersecting the first direction, e.g., y-direction. In order to improve RTS noise characteristics, the drive transistors OD1 to OD4 may have a gate length longer than a gate length of the select transistors OS1 to OS4 and the reset transistors OR1 to OR4.

The first photoelectric elements OPD1 to OPD4 in the first to fourth pixels PX1 to PX4 may be connected to at least a portion of first semiconductor devices OR1 to OR4, OS1 to OS4, and OD1 to OD4, through via electrodes VE1 to VE4 in the first to fourth pixel regions PA1 to PA4. Referring to the third pixel region PA3 as an example, a via electrode VE3 extending in one direction (e.g., z-axis direction) may be in the third pixel region PA3. One surface of the via electrode VE3 may be connected to the first photoelectric element OPD3 in a lower portion of the third pixel region PA3. Another surface of the via electrode VE3 may be connected to first semiconductor devices OR3, OS3, and OD3 in the first circuit C1 of the third pixel PX3 via a metal line ML and a contact CNT.

With reference to FIG. 5, at least portions of the first semiconductor devices OR1 to OR4, OS1 to OS4, and OD1 to OD4, connected to respective via electrodes VE1 to VE4, may be in different pixel regions. As an example, referring to the second pixel region PA2 among the first semiconductor devices OR2, OS2, and OD2 connected to the second via electrode VE2, the reset transistor OR2 may be in the second pixel region PA2 and the select transistor OS2 and the drive transistor OD2 may be in the first pixel region PA1. Similarly, referring to the third pixel PA3, among the first semiconductor devices OR3, OS3, and OD3, connected to the third via electrode VE3, the reset transistor OR3 may be in the third pixel region PA3 and the select transistor OS3 and the drive transistor OD3 may be in a sixth pixel region PA6.

A second circuit C2, connected to the second photoelectric elements SPD1 to SPD4 in the first to fourth pixel regions PA1 to PA4, may share at least portions of the second semiconductor devices TX1 to TX4, DX1, DX2, RX, and SX in one pixel group PG. With reference to FIG. 4, the reset transistor RX, the select transistor SX, the first drive transistor DX1, and the second drive transistor DX2, excluding the transfer transistors TX1 to TX4, may be shared in one pixel group PG.

Since at least portions of second semiconductor devices TX1 to TX4, DX1, DX2, RX, and SX are shared within one pixel group PG, an area occupied by the second semiconductor devices TX1 to TX4, DX1, DX2, RX, and SX in one pixel group PG may be smaller than an area occupied by the first semiconductor devices OR1 to OR4, OS1 to OS4, and OD1 to OD4. In addition, in the first to fourth pixel regions PA1 to PA4, respectively, an area occupied by the second semiconductor devices TX1 to TX4, DX1, DX2, RX, and SX may be smaller than an area occupied by the first semiconductor devices OR1 to OR4, OS1 to OS4, and OD1 to OD4, respectively. The area occupied by the semiconductor devices may be an area of a semiconductor substrate covered by an active region ACT and a gate electrode G of the respective semiconductor devices.

Referring to FIG. 5, each of the first to fourth pixel regions PA1 to PA4 may include one of the transfer transistors TX1 to TX4. In an example embodiment, the transfer transistors TX1 to TX4 in the first to fourth pixel regions PA1 to PA4, respectively, may be at positions that are not adjacent to the pixel separation region DTI. Referring to the first pixel region PA1 as an example, other semiconductor devices OR1, OS2, and OD2 and the via electrode VE1 may be in the periphery of the transfer transistor TX1, so as not to be adjacent to the pixel separation region DTI.

With reference to FIG. 5, the reset transistor RX in the second circuit C2 may be in the third pixel region PA3. The first drive transistor DX1 may be in the fourth pixel region PA4. The second drive transistor DX2 may be in the second pixel region PA2. In addition, the select transistor SX in the second circuit C2 may be in a seventh pixel region PA7 of another adjacent pixel group PG2. For example, at least one of the second semiconductor devices RX, SX, DX1, and DX2 shared by the second circuit C2 may be in a region of the adjacent pixel group PG2, different from the pixel group PG in which the transfer transistors TX1 to TX4 are arranged.

In an example embodiment, a horizontal or vertical width of each of pixel regions PA1 to PA8 may be equal to or less than 2 μm. In an example embodiment, two or more pixel regions PA1 to PA8 adjacent to each other may be defined as one pixel group PG. The second circuit C2 may share the reset transistor RX, the select transistor SX, the first drive transistor DX1, and the second drive transistor DX2, within one pixel group PG. Further, at least one of the second semiconductor devices RX, SX, DX1, and DX2 shared by the second circuit C2 may be in another adjacent pixel group. A portion of the elements in the first circuit C1 may be in other adjacent pixel regions PA1 to PA8. Thus, the semiconductor devices in the first circuit Cl and the second circuit C2 may be efficiently arranged within a limited area. In addition, since a charge is generated by light of different colors by the photoelectric elements in the respective pixel regions PA1 to PA8, color reproducibility of the image sensor may be improved.

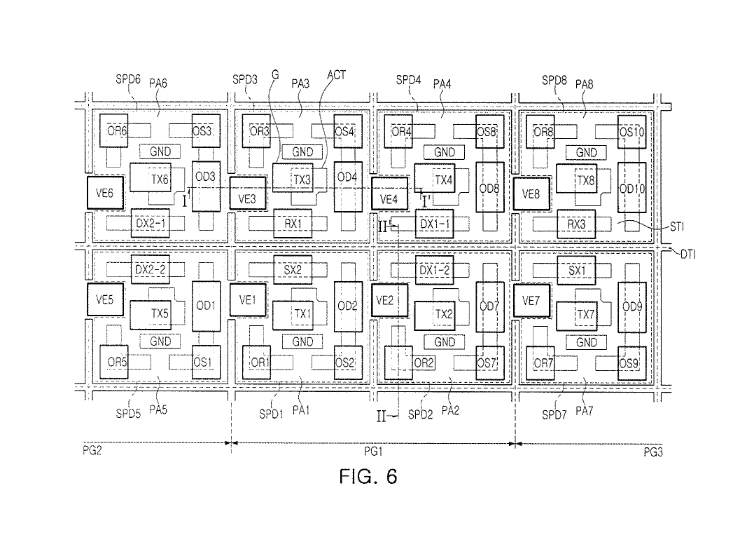

FIG. 6 illustrates another layout embodiment of semiconductor devices in an image sensor, which may correspond to any of the image sensor embodiments herein.

Referring to FIG. 6, the image sensor may include a plurality of pixel regions PA1 to PA8 repeatedly arranged. The pixel regions PA1 to PA8 may be separated by a pixel separation region DTI. In addition, the pixel regions PA1 to PA8 may form the pixel groups PG1 to PG3. FIG. 6 illustrates a first pixel group PG1, a second pixel group PG2, and a third pixel group PG3. Each of the pixel groups PG1 to PG3 may include four pixel regions PA1 to PA8 arranged in a 2×2 matrix. For example, the first pixel group PG1 may include first to fourth pixel regions PA1 to PA4.

In the example embodiment of FIG. 6, each of the pixel regions PA1 to PA8 may include two or more photoelectric elements that are stacked on each other in one direction, e.g., a z-axis direction. A plurality of semiconductor devices may be formed on the photoelectric elements. The plurality of semiconductor devices may generate electrical signals using charges generated in the respective photoelectric elements, and may output the electrical signals through column lines.

In an example embodiment, the second photoelectric elements SPD1 to SPD8 may be beneath the semiconductor devices in each of the pixel regions PA1 to PA8. The first photoelectric elements may further be beneath the second photoelectric elements SPD1 to SPD8. The first photoelectric elements, and the second photoelectric elements SPD1 to SPD8 may absorb light in different wavelength bands to generate electric charges. The first photoelectric elements may be organic photodiodes, and the second photoelectric elements SPD1 to SPD8 may be semiconductor photodiodes.

Referring to FIG. 6, the pixel separation region DTI may not be formed in at least a portion of a boundary between the pixel regions PA1 to PA8. The via electrodes VE1 to VE8 may be formed in a region in which the pixel separation region DTI is not formed. The via electrodes VE1 to VE8 may be adjacent to the second photoelectric elements SPD1 to SPD8 and may extend in one direction (e.g., a z-axis direction) to be connected to the first photoelectric elements beneath the second photoelectric elements SPD1 to SPD8.

The semiconductor devices in each of the pixel regions PA1 to PA8 may include an active region ACT and a gate electrode G. The active region ACT may provide a source/drain region of the respective semiconductor devices. The gate electrode G may intersect the active region. An area and a shape of the active region ACT and the gate electrode G of each of the semiconductor devices may be variously modified.

Each of the pixel regions PA1 to PA8 in the image sensor may include, for example, semiconductor devices processing charges generated in photoelectric elements in adjacent pixel regions PA1 to PA8. For example, at least a portion of the semiconductor devices may be in other adjacent pixel regions PA1 to PA8 to generate electrical signals using charges generated in the photoelectric elements in the respective pixel regions PA1 to PA8.

In the example embodiment illustrated in FIG. 6, the first photoelectric device in the first pixel region PA1 may be connected to the first semiconductor devices OR1, OS1, and OD1 via the first via electrode VE1. The first semiconductor devices OR1, OS1, and OD1 may be a reset transistor OR1, a select transistor OS1, and a drive transistor OD1 and may generate a first electrical signal VOpix using a charge generated in the first photoelectric element OPD1.

At least a portion of the first semiconductor devices OR1, OS1, and OD1, which are connected to the photoelectric element in the first pixel region PA1, may not be in the first pixel region PA1. With reference to FIG. 6, among the first semiconductor devices OR1, OS1 and OD1, the select transistor OS1 and the drive transistor OD1, may be in the sixth pixel region PA6 other than the first pixel region PA1. The sixth pixel region PA6 may be adjacent to the first pixel region PAL Thus, the sixth pixel region PA6 may include a portion of the first semiconductor devices, for example, first semiconductor devices OS1 and OD1, generating an electrical signal using a charge generated in the first photoelectric element OPD1 of the adjacent first pixel region PA1.

In the case of the second pixel region PA2, a portion of the first semiconductor devices OR2, OS2, and OD2 may be in the first pixel region PAl to process a charge generated in the first photoelectric element OPD2 of the second pixel region PA2. For example, the first pixel region PA1 may include a portion of the first semiconductor devices (e.g., OS2 and OD2) to generate an electrical signal using a charge generated in the adjacent second pixel region PA2. In addition, the second pixel region PA2 may include a portion of the first semiconductor devices (e.g., OS7 and OD7) connected to a via electrode VE7 of an adjacent seventh pixel region PA7.

Referring to FIG. 6, pixels PX1 to PX4 of the first pixel group PG1 may include transfer transistors TX1 to TX4 for determining whether to transmit charges generated in the first photoelectric elements SPD1 to SPD4 to a floating diffusion. In an example embodiment, each of the pixels PX1 to PX4 may include one of the transfer transistors TX1 to TX4.

Charges generated in the second photoelectric elements SPD1 to SPD4 in the first pixel group PG1 may be converted to second electrical signals VSpix by the second semiconductor devices TX1 to TX4, DX1-1, DX1-2, RX, and SX. The first to fourth pixels PX1 to PX4 in the first pixel group PG1 may share a reset transistor RX1, a select transistor SX1, a first drive transistor DX1-1, and a second drive transistor DX1-2. In an example embodiment, at least one of the reset transistor RX1, the select transistor SX1, the first drive transistor DX1-1, and the second drive transistor DX1-2, shared by the first to fourth pixels PX1 to PX4, may not be in the first pixel group PG1.

With reference to FIG. 6, among the elements shared by the first to fourth pixels PX1 to PX4, the select transistor SX1 may be in the third pixel group PG3 adjacent to the first pixel group PG1. In addition, the select transistor SX2, shared by the second pixel group PG2, may be in the first pixel group PG1.

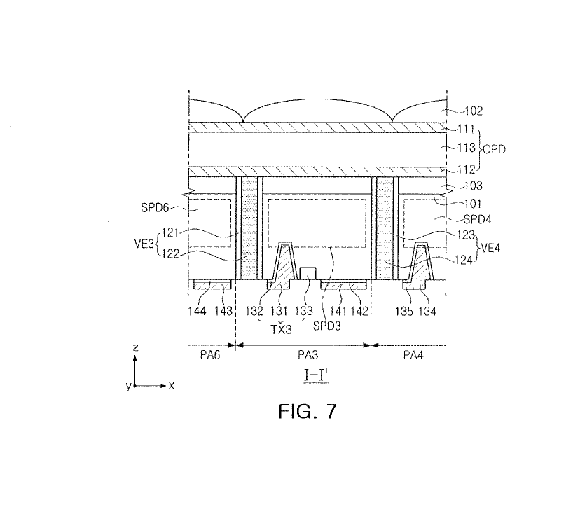

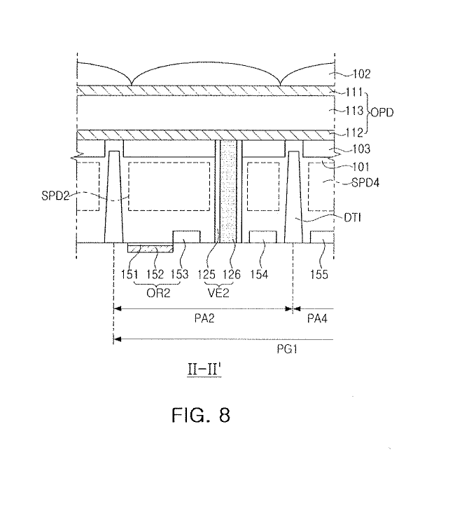

FIG. 7 illustrates an embodiment of an image sensor taken along line I-I′ in FIG. 6. FIG. 8 illustrates an embodiment of the image sensor taken along line II-II′ in FIG. 6.

Referring to FIG. 7, the image sensor may be a backside-illuminated image sensor. Light incident externally may be transferred to photoelectric elements OPD, SPD3, SPD4, and SPD6 via a microlens 102. The photoelectric elements may include a first photoelectric element OPD and second photoelectric elements SPD3, SPD4, and SPD6.

Referring to FIG. 6, a third pixel region PA3 may include a first photoelectric element OPD and a second photoelectric element SPD3 stacked in a single direction, e.g., a z-axis direction. The first photoelectric element OPD and the second photoelectric element SPD3 may receive light of different colors to generate electric charges. In an example embodiment, the first optoelectronic device OPD may be an organic photodiode, and the second optoelectronic device SPD3 may be a semiconductor photodiode. The second photoelectric element SPD3 may be in a semiconductor substrate 101 and may receive light passing through a color filter 103 to generate a charge carrier. In an example embodiment, a color of light passing through the color filter 103 in the third pixel region PA3 may differ from colors of light passing through color filters 103 in a fourth pixel region PA4 and a sixth pixel region PA6.

The third pixel region PA3 may include a via electrode VE3 adjacent to a boundary thereof with the sixth pixel region PA6. The via electrode VE3 may include an insulating portion 121 and a conductive portion 122. The conductive portion 122 may be electrically isolated from the semiconductor substrate 101 and the second photoelectric element SPD3 by the insulating portion 121. One surface of the via electrode VE3 may be connected to the first photoelectric element OPD.

In an example embodiment, the first photoelectric element OPD may include a first electrode layer 111 facing a second electrode layer 112. The second electrode layer 112 may be connected to the via electrode VE3. A color select layer 113 may generate a charge by a photoelectric effect and may be between the first electrode layer 111 and the second electrode layer 112. The color select layer 113 may include an organic material and may include a p-type layer in which main carriers are holes and an n-type layer in which main carriers are electrons. The color select layer 113 may generate an electrical charge based on light of a specific wavelength band. By way of example, the color select layer 113 may generate an electrical charge based on green color light. Light of colors other than green may be transferred to the second photoelectric element SPD3 through the color filter 103.

The first and second electrode layers 111 and 112 may be formed of a transparent conductive material (e.g., ITO, IZO, ZnO or SnO₂) or a semitransparent conductive material, e.g., a material of a metal thin film. In an example embodiment, the first electrode layer 111 may have a work function greater than or equal to a work function of the second electrode layer 112.

The second photoelectric element SPD3 may receive light passing through the color filter 103 to generate electric charges. In an example embodiment, the color filter 103 may allow red or blue light to pass therethrough. A color of light passing through the color filter 103 of the third pixel region PA3 may be different from a color of light passing through the color filter 103 of the fourth and sixth pixel regions PA4 and PA6.

A plurality of semiconductor devices may be on the second photoelectric element SPD3. The plurality of semiconductor devices may generate electrical signals using charges generated in the first photoelectric element OPD and the second photoelectric element SPD3. Referring to FIG. 6, the third pixel region PA3 may include a transfer transistor TX3 which may include a transfer gate electrode 131 and a floating diffusion 133. The transfer gate electrode 131 may be formed in such a manner that at least a portion of the transfer gate electrode 131 is embedded in the semiconductor substrate 101. A gate insulating layer 132 may be between the transfer gate electrode 131 and the semiconductor substrate 101.

The floating diffusion 133 may be a region doped with an n-type impurity. An electric charge generated in the second photoelectric element SPD3 may be transferred to the floating diffusion 133 by a voltage input to the transfer gate electrode 131. For example, when a predetermined level of voltage is input to the transfer gate electrode 131, a channel region in which a charge may be transferred may be between the floating diffusion 133 and the second photoelectric element SPD3.

A gate electrode 141 of a drive transistor OD4 in the third pixel region PA3 may have a horizontal structure. A gate insulating layer 142 may be between the gate electrode 141 and the semiconductor substrate 101. The gate electrode 141 of the drive transistor OD4 in the third pixel region PA3 may be electrically connected to a via electrode VE4 in a fourth pixel region PA4. Thus, the drive transistor OD4 in the third pixel region PA3 may generate an electrical signal using an electric charge generated by the first photoelectric element OPD in the fourth pixel region PA4. Similarly, the gate electrode 143 of the drive transistor OD3 in the sixth pixel region PA6 may be connected to the via electrode VE3 in the third pixel region PA3.

Referring to FIG. 7, a pixel separation region DTI may be between the pixel regions PA2 and PA4. The pixel separation region DTI may extend from an upper surface of the semiconductor substrate 101 and may be provided to separate the second photoelectric elements SPD2 and SPD4 from each other. The second photoelectric elements SPD2 and SPD4 may not be formed in a region in which the pixel separation region DTI is formed and in a region in which the via electrode VE2 is formed. Thus, an area of a light-receiving region of each of the second photoelectric elements SPD2 and SPD4 in the respective pixel regions PA2 and PA4 may be smaller than that of a light-receiving region of the first photoelectric element OPD. The light- receiving area may be defined as an X-Y plane, e.g., a plane intersecting a direction in which light is incident.

With reference to FIG. 8, a gate electrode 151 in elements processing a charge generated in the first photoelectric element OPD, or active regions 153 to 155, may be adjacent to the pixel separation region DTI. For example, only one active region 153 of the reset transistor OR3 is illustrated in a cross-sectional view taken along line II-II′, which is on a base in which a source region and a drain region of the reset transistor OR3 intersect each other.

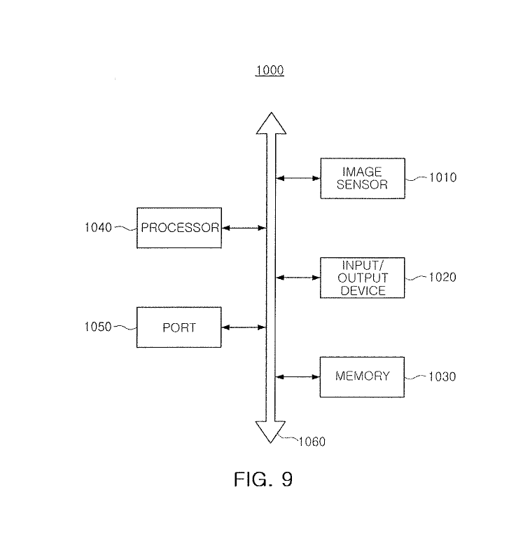

FIG. 9 illustrates an embodiment of an electronic device including an image sensor according to any of the example embodiments described herein. The electronic device may be, for example, a computer apparatus 1000.

Referring to FIG. 9, a semiconductor device may be applied to the computer apparatus 1000. The computer apparatus 1000 may include an image sensor 1010, an input/output device 1020, a memory 1030, a processor 1040, and a port 1050. The semiconductor device 10 may be applied to the image sensor 1010, the memory 1030, and the processor 1040. The computer apparatus 1000 may further include a wired/wireless communications device, a power supply device, and other features.

The port 1050 may be a device to allow the computer apparatus 1000 to communicate with a video card, a sound card, a memory card, a USB device, or another device. The computer apparatus 1000 may be based on a comprehensive concept, including but not limited to a smartphone, a tablet PC, a smart wearable device, a desktop computer, and a laptop computer.

The processor 1040 may perform specific arithmetic operations commands, tasks, and the like. The processor 1040 may be, for example, a central processing unit (CPU) or a microprocessor unit (MCU) and may communicate with the memory 1030, the input/output device 1020, the image sensor 1010, and other devices connected to the port 1050 via a bus 1060.

The memory 1030 may be a storage medium for storing data to be used for operations of the computer apparatus 1000, multimedia data, or the like. The memory 1030 may include a volatile memory, such as a random access memory (RAM), or a non-volatile memory, such as a flash memory and the like. In addition, the memory 1030 may include at least one of a solid state drive (SSD), a hard disk drive (HDD), and an optical drive (ODD), as a storage device. The input/output device 1020 may include an input device such as a keyboard, a mouse, a touchscreen, and the like, for a user. An output device such as a display, an audio output unit, and the like.

The image sensor 1010 may include a sensor circuit having a plurality of transistors. The pixel circuit of the image sensor 1010 may include semiconductor devices arranged according to various example embodiments. A plurality of pixels may form one pixel group. Pixel circuits in one pixel group may share a column line, thereby increasing circuit integration. Further, by detecting signals from photoelectric elements in a single pixel in every scanning period, in which respective pixels are activated on a row basis, a change in a coupling component between pixels may be significantly reduced. As a result, the occurrence of fixed pattern noise in a horizontal direction may be significantly decreased or eliminated.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods described herein.

The processors and other signal generating and signal processing features of the disclosed embodiments may be implemented in logic which, for example, may include hardware, software, or both. When implemented at least partially in hardware, the processors and other signal generating and signal processing features may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the processors and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

In accordance with one or more of the aforementioned embodiments, semiconductor devices connected to a first photoelectric element and semiconductor devices connected to a second photoelectric element may be efficiently arranged in a pixel region of a limited area. By arranging semiconductor devices in a layout structure according to the aforementioned example embodiments, characteristics of semiconductor devices in a limited area may be improved and performance of an image sensor may be enhanced.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

What is claimed is:

1. An image sensor including a plurality of pixel regions, comprising:
a plurality of first photoelectric elements;
a plurality of second photoelectric elements beneath the plurality of first photoelectric elements; and
a pixel circuit including first semiconductor devices and second semiconductor devices beneath the plurality of second photoelectric elements, the first semiconductor devices connected to at least one of the plurality of first photoelectric elements and the second semiconductor devices connected to at least one of the plurality of second photoelectric elements, wherein the first semiconductor devices are connected to different first photoelectric elements among the plurality of first photoelectric elements and are in one of the plurality of pixel regions.

2. The image sensor as claimed in claim 1, wherein:
the first semiconductor devices include a first reset transistor, a first select transistor, and a first drive transistor, and
the first select transistor and the first drive transistor in one of the plurality of pixel regions are connected to one of the plurality of first photoelectric elements different from another one of the plurality of the first photoelectric elements connected to the first reset transistor.

3. The image sensor as claimed in claim 2, wherein an active region of the first select transistor is connected to an active region of the first drive transistor.

4. The image sensor as claimed in claim 3, wherein:
the active region of the first select transistor extends in a first direction, and
the active region of the first drive transistor extends in a second direction intersecting the first direction.

5. The image sensor as claimed in claim 2, wherein a gate length of the first select transistor is shorter than a gate length of the first drive transistor.

6. The image sensor as claimed in claim 1, wherein:
the first semiconductor devices provide first circuits,
the second semiconductor devices provide second circuits, and
two or more adjacent pixel regions among the plurality of pixel regions provide a single pixel group.

7. The image sensor as claimed in claim 6, wherein:
the first circuits in the single pixel group share a first column line, and
the second circuits in the single pixel group share a second column line.

8. The image sensor as claimed in claim 6, wherein the second circuits in the single pixel group share at least a portion of the second semiconductor devices.

9. The image sensor as claimed in claim 8, wherein at least one of the second semiconductor devices shared by the second circuits in the single pixel group is in another, adjacent pixel group.

10. The image sensor as claimed in claim 1, further comprising:
a separation region between the plurality of pixel regions,
wherein the first semiconductor devices are adjacent to the separation region.

11. The image sensor as claimed in claim 10, further comprising:
a via electrode electrically connecting the first semiconductor devices to the plurality of first photoelectric elements to each other, the via electrode at a boundary between the plurality of pixel regions which does not include the separation region.

12. The image sensor as claimed in claim 1, wherein a light-receiving region of the plurality of first photoelectric elements is greater than a light-receiving region of the plurality of second photoelectric elements.

13. The image sensor as claimed in claim 1, wherein the plurality of first photoelectric elements and the plurality of second photoelectric elements receive light in different wavelength bands to generate corresponding charges.

14. An image sensor, comprising:
a semiconductor substrate including a plurality of pixel regions;
a plurality of first photoelectric elements on a semiconductor substrate;
a plurality of second photoelectric elements in the semiconductor substrate;
a pixel circuit beneath the plurality of second photoelectric elements and including first semiconductor devices electrically connected to at least one of the plurality of first photoelectric elements and second semiconductor devices electrically connected to at least one of the plurality of second photoelectric elements; and
via electrodes penetrating through the semiconductor substrate and connecting the first semiconductor devices to at least one of the plurality of first photoelectric elements, wherein portions of the first semiconductor devices connected to one of the via electrodes are in different pixel regions among the plurality of pixel regions.

15. The image sensor as claimed in claim 14, wherein an area occupied by the first semiconductor devices is greater than an area occupied by the second semiconductor devices in each of the plurality of pixel regions.

16. The image sensor as claimed in claim 14, wherein the portions of the first semiconductor devices connected to one of the via electrodes share an active region.

17. The image sensor as claimed in claim 14, wherein, in each of the plurality of pixel regions, a light-receiving region of the plurality of the first photoelectric elements is greater than a light-receiving region of the plurality of second photoelectric elements.

18. The image sensor as claimed in claim 14, wherein the second semiconductor devices include a reset transistor, a select transistor, a drive transistor, and a transfer transistor.

19. The image sensor as claimed in claim 18, wherein:
two or more adjacent pixel regions among the plurality of pixel regions provide a single pixel group, and
the plurality of second photoelectric elements in the single pixel group share the reset transistor, the select transistor, and the drive transistor.

20. An image sensor, comprising:
first to third pixel groups adjacent to each other,
wherein each of the first to third pixel groups includes a plurality of first photoelectric elements, a plurality of second photoelectric elements beneath the plurality of first photoelectric elements, and a pixel circuit including first semiconductor devices and second semiconductor devices beneath the plurality of second photoelectric elements, and
wherein at least one of the first semiconductor devices in the first pixel group is connected to at least one of the plurality of first photoelectric elements in the second pixel group, and at least one of the second semiconductor devices in the first pixel group is connected to at least one of the plurality of second photoelectric elements in the third pixel group.
